(19) United States
(12) Patent Application Publication
(10) Pub. No.: US 2008/0073738 A1
(43) Pub. Date: Mar. 27, 2008

(54) Light-receiving diode

(75) Inventors: Wei Chang, San Chung City (TW); Shih-Chieh Huang, San Chung City (TW); Huai-Fu Chen, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/526,232

(22) Filed: Sep. 25, 2006

(51) Int. Cl. H01L 31/0203

(52) U.S. Cl. 257/433; 257/E31.117

(57) ABSTRACT

An improved structure of light-receiving diode is disclosed. The light-receiving diode generally comprises: a support frame on which a transimpedance amplifier and a light-receiving chip having a built-in capacitor are located; and a plurality of pins. The light-receiving chip is attached to the support frame via a conducting spacer, and connected to other pins via several bonding wires. The aforesaid components and the top of the pins are packaged by a sealing adhesive. Accordingly, the manufacture process can be simplified and the noise can be reduced.

### FIELD OF THE INVENTION

The present invention relates to an improved structure of light-receiving diode able to simplify manufacture process and reduce noise effectively for use together with a light-emitting diode or the like.

### BACKGROUND OF THE INVENTION

A laser diode, which acts as a light source, is typically applied to the current optical fiber system. After being packaged, the laser diode becomes a laser diode device. The conventional VCSEL (Vertical Cavity Surface Emitting Laser) requires a base that has a larger area. As shown in FIG. 5, three pins are attached to the bottom of the large-area base A. Besides, a mounting device B, a photo-diode chip C, and a VCSEL chip D are formed sequentially on the base A, and all covered with a metal cover E having a lens E1.

The structure of an improved light-receiving diode is approximately identical to that of the laser diode. The difference between them consists in that the VCSEL chip is replaced by a light-receiving chip. When it is applied to the optical fiber for signal transmission, as shown in FIG. 6, the laser diode device 1 is mounted on the inside of a metal base 2, and fixed thereon by a fixing adhesive 3. The aforesaid metal base 2 is fixedly coupled with a fixing sleeve 4. A hollow ceramic tube 5 is coaxially mounted on the inside of the sleeve 4. A cylindrical ceramic plug 6 is coaxially mounted on the inside of the ceramic tube 5. The rear end of the ceramic plug 6 is polished to form a bevel 7 for preventing the light from being reflected directly to the laser diode, thereby avoiding the interference from noise.

Furthermore, an optical fiber 8 is coaxially mounted on the inside of the ceramic plug 6 to allow the light emitted from the laser diode device 1 to be gathered into a fiber core of the optical fiber 8, and then guided along the fiber core of the optical fiber 8 in an optical fiber connector that couples with the sleeve 4. The assembly of the above-mention packaging structure constitutes a light-emitting module. If the above-mentioned laser diode device 1 is replaced with a photodetector, a light-receiving module is formed.

However, the light-receiving diode is designed for only receiving signals so it only produces a little heat. Its entire structure-is similar to that of the laser diode that sends out signals. As a result, the light-receiving diode requires the large-area base A and the metal cover E. Accordingly, its manufacture cost is increased and its manufacture procedure is complicated.

In view of the foregoing description, the motive of the present invention is to provide the general public with a light-receiving diode able to simplify manufacture process and reduce noise.

### SUMMARY OF THE INVENTION

It is a main object of the present invention to provide an improved structure of light-receiving diode that simplifies manufacture process and reduces noise.

In order to achieve the above-mentioned object, a light-receiving diode is disclosed. The light-receiving diode generally comprises: a support frame on which a transimpedance amplifier and a light-receiving chip having a built-in capacitor are located; and a plurality of pins. The light-receiving chip is attached to the support frame via a conducting spacer, and connected to other pins via several bonding wires. The aforesaid components and the top of the pins are packaged by a sealing adhesive. Accordingly, the manufacture process can be simplified and the noise can be reduced.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational diagram showing a preferred embodiment of the present invention.

FIG. 2 is a schematic diagram showing the sleeve that couples with the structure of the preferred embodiment of the present invention.

FIG. 3 is a cross-sectional, assembled diagram of FIG. 2.

FIG. 4 is a schematic diagram showing the usage of the present invention.

FIG. 5 is a cross-sectional diagram showing the conventional light emitting/receiving module.

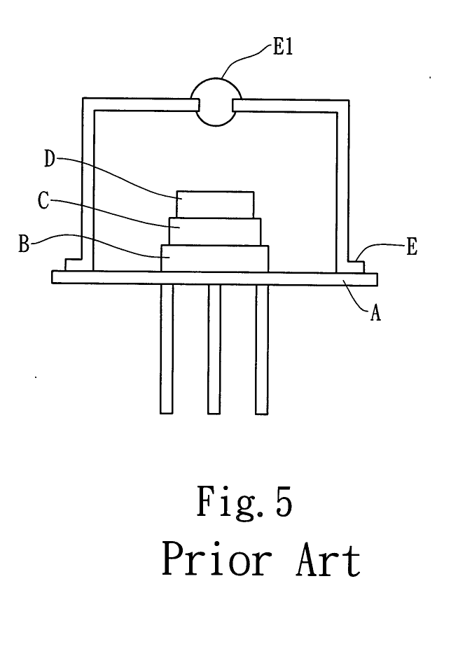

FIG. 6 is a schematic diagram showing the usage of the conventional light emitting/receiving module shown in FIG. 5.

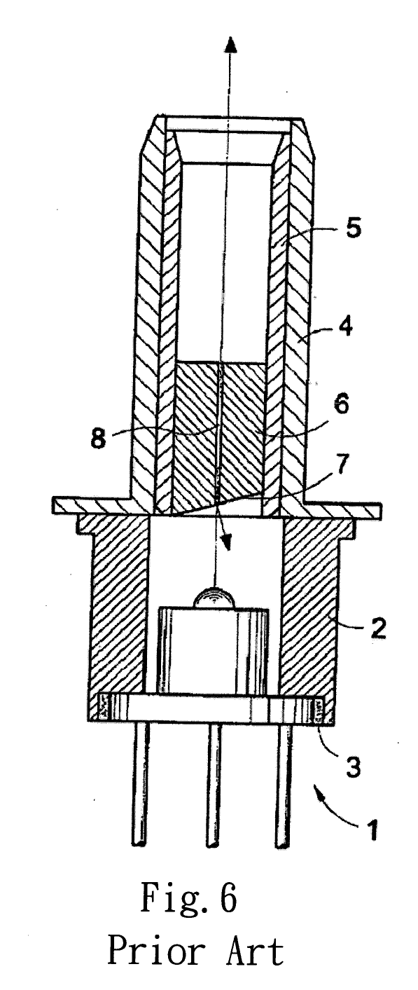

### DETAILED DESCRIPTION OF THE PREFERRED EMBODIMENT

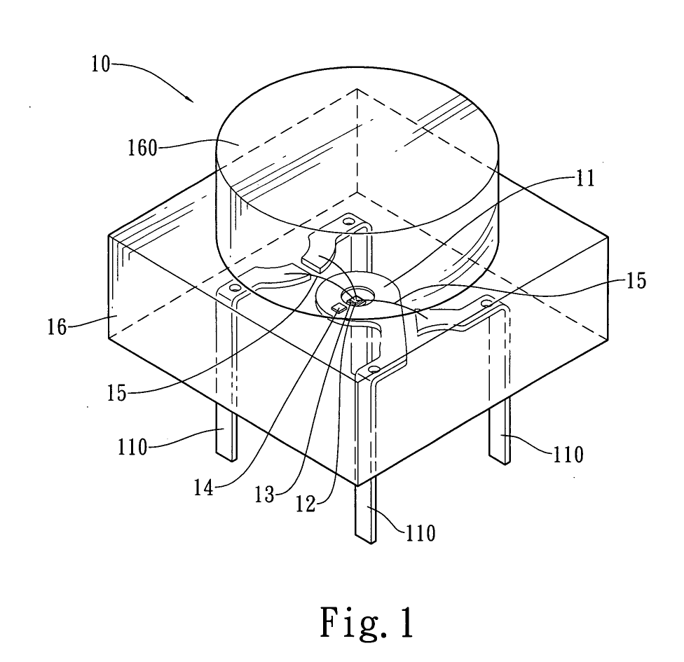

Referring to FIG. 1, a light-receiving diode 10 of the present invention generally comprises a support frame 11 and a plurality of pins 110. A chip base is formed on the support frame 11, and coupled with a light-receiving chip 12 via a spacer 13. The surface of the spacer 13 is plated with a layer of conducting metal. In addition, a transimpedance amplifier 14 is attached to the support frame 11 near the chip base. The light-receiving chip 12 has a built-in capacitor. Besides, the light-receiving chip 12 is connected to other pins 110 via several bonding wires 15. After forming the bonding wires 15, the top of the pins 110, the bonding wires 15, the light-receiving chip 12, the spacer 13, and the transimpedance amplifier 14 are all packaged by a sealing adhesive 16, and thus the assembly of the light-receiving diode 10 is completed. The sealing adhesive 16 has a protrudent unit 160 on the top.

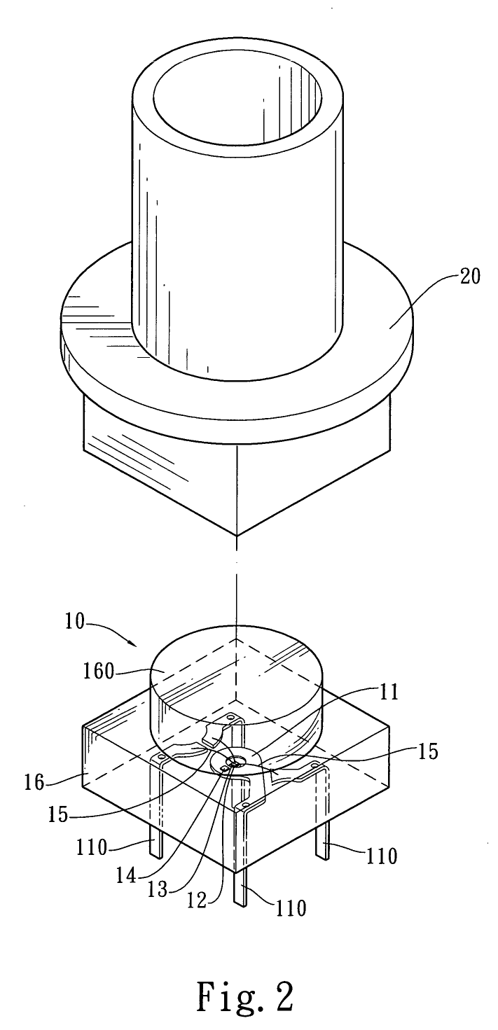

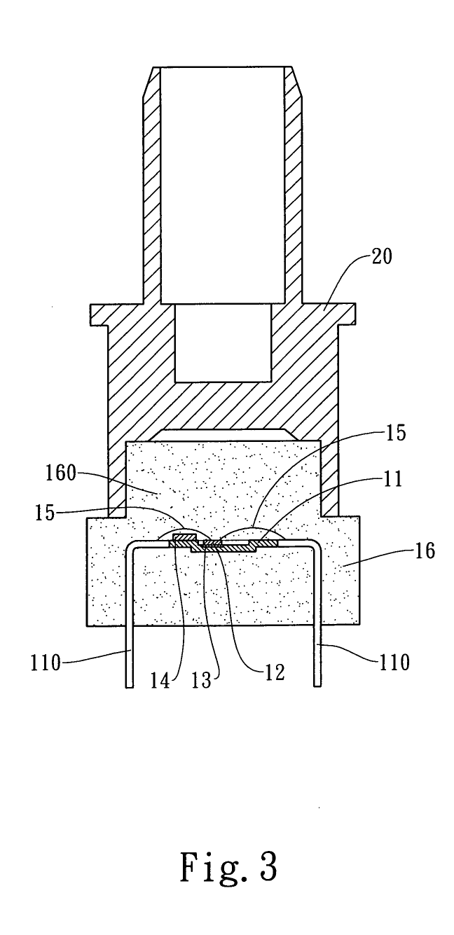

The above-mentioned light-receiving diode 10 can be coupled with a sleeve 20 by inserting the protrudent unit 160 of the sealing adhesive 16 into the sleeve 20 directly, as shown in FIGS. 2 and 3. The sleeve 20 is composed of two regions having different diameters. One of these two regions has a diameter corresponding to that of the protrudent unit 160 of the sealing adhesive 16 so that the conventional metal base and the conventional step of forming the fixing adhesive can be omitted.

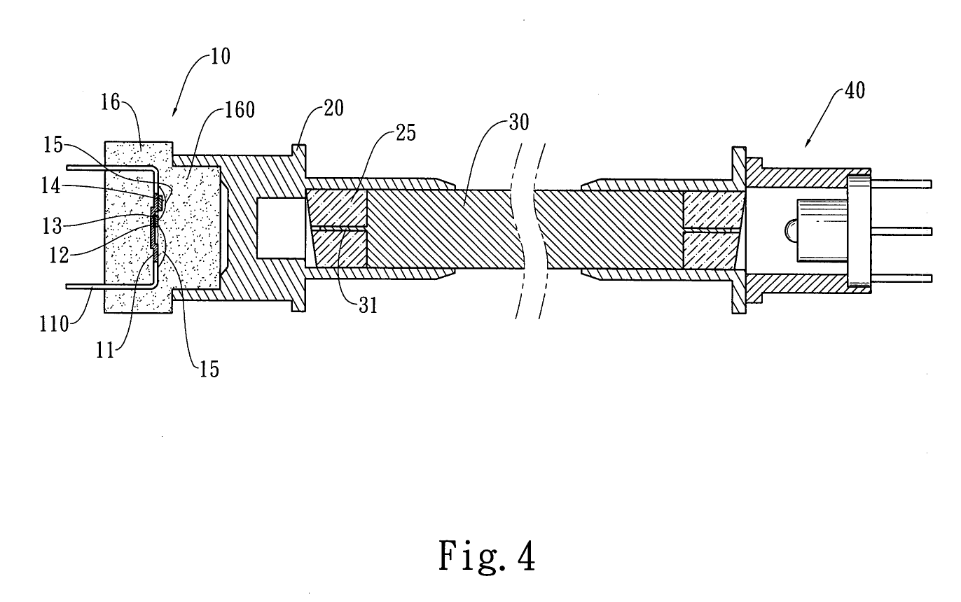

Referring to FIG. 4, the light-receiving diode 10 is coupled with the sleeve 20 by inserting the protrudent unit 160 into the sleeve 20 to allow the light-receiving chip 12 to face the center of the sleeve 20. The other end of the sleeve 20 is sleeved onto a ceramic plug 25, which has a through hole on the center and a fiber 30 penetrating therethrough coaxially. In addition, the other end of the fiber 30 is connected to a light emitter 40, whereby the light emitted from the light emitter 40 can be guided to the light-receiving diode 10 along a fiber core 31 of the fiber 30.

Furthermore, the total structure of light-receiving diode 10 including the lateral surfaces of the sealing adhesive 16 and the protrudent unit 160 are optionally plated with a layer of metal film to guard against the electromagnetic interference. Besides, the top surface of the protrudent unit 160 is optionally plated with a layer of anti-reflection film to increase optical efficiency.

In accordance with the foregoing description, the apparatus of the present invention has the following advantages:

1. The light-receiving chip of the light-receiving diode has a built-in capacitor so that the step for coupling with the capacitor is thus omitted, thereby simplifying the manufacture process and reducing the noise.

2. The sealing adhesive of the light-receiving diode can be coupled with the sleeve easily by means of its specific shape, whereby the components of the light-receiving module can be simplified and the production cost can be reduced significantly.

3. The light-receiving diode generates almost no heat so that the heat dissipation issue of the assembled light-receiving diode module can be ignored and that the sealing adhesive can be applied directly.

In summary, the improved structure of light-receiving diode disclosed in the present invention indeed achieves the anticipated objects. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light-receiving diode comprising:
a support frame;
a plurality of pins;
a transimpedance amplifier located on said support frame;
a light-receiving chip located on said support frame via a spacer and connected to parts of said plurality of pins via a plurality of bonding wires, said light-receiving chip having a built-in capacitor; and
a sealing adhesive for packaging aforesaid components and the top of said plurality of pins.

2. The light-receiving diode of claim 1, wherein said support frame has a chip base formed thereon for coupling with said light-receiving chip.

3. The light-receiving diode of claim 1, wherein the surface of said spacer is plated with a layer of conducting metal.

4. The light-receiving diode of claim 1, wherein the entire lateral surface of said light-receiving diode is plated with a layer of metal film to guard against electromagnetic interference.

5. The light-receiving diode of claim 1, wherein the top surface of said light-receiving diode is plated with a layer of anti-reflection film to increase optical efficiency.
